(19) United States
(12) Patent Application Publication
(10) Pub. No.: US 2022/0373603 A1
(43) Pub. Date: Nov. 24, 2022

(54) CAPACITIVELY COUPLED DATA LINK FOR A SEALED BATTERY

(71) Applicant: Walter BACHAROWSKI, Henderson, NV (US)

(72) Inventor: Walter BACHAROWSKI, Henderson, NV (US)

(21) Appl. No.: 17/771,642

(22) PCT Filed: Oct. 29, 2020
(86) PCT No.: PCT/US2020/057901

§ 371 Date: Apr. 25, 2022

Related U.S. Application Data
(60) Provisional application No. 62/927,915, filed on Oct. 30, 2019.

(51) Int. Cl. G01R 31/371; H01M 10/42; H04B 5/00; G01R 31/367

(52) U.S. Cl. CPC G01R 31/371; H01M 10/4257; H04B 5/0012; G01R 31/367; H01M 2010/4278

(57) ABSTRACT

A capacitively coupled data link for a battery is disclosed. The battery comprises a battery cell and a battery management system. The battery is disposed in a battery case. The data li [symbol] communicates data between the battery management system and a data terminal disposed outside of the battery case. The data link comprises an interior date link portion coupled to the battery management system. The interior data link portion comprises an interior electrode disposed on an inside surface of the battery case and an interior transceiver disposed inside of the battery case coupled to the interior electrode. The data link further comprises an exterior data link portion coupled to data terminal. The exterior data link portion comprises an exterior electrode disposed o [symbol] outside surface of the battery case opposite the interior electrode, and an exterior transceiver disposed outside of the battery case coupled to the exterior electrode. The interior electrode, the exterior electrode and the battery case disposed therebetween form a capacitive communication link between the interior data link portion and the exterior data link portion.

### BACKGROUND

Batteries may comprise one or more electrochemical cells, such as lithium ion battery cells, contained within a battery case (or housing). If more than one electrochemical cell is contained in the battery case, the electrochemical cells are typically electrically interconnected. Certain ones of such batteries may include a battery management system, or BMS, which may monitor and/or control such battery functions as charging and discharging the electrochemical cells.

In certain situations, a battery, such as a marine battery, may be contained within a sealed case, such as to protect the electrochemical cells and/or associated BMS from such environmental factors as water.

It may be desirable to externally communicate with the BMS, such as to determine the status/health of the associated electrochemical cells and/or BMS, or to download software updates for the BMS. However, in situations such as where the BMS is contained within a sealed battery case, the seal of the sealed battery case typically must be broken in order to make a physical electrical contact with, and thereby communicate with, the EMS.

The present invention is provided to address this and other problems.

### SUMMARY

In accordance with the present disclosure, a capacitively coupled datalink is provided with the BMS hardware inside a battery without the addition of connectors that feedthrough the case. The data link may comprise two areas of thin metal electrodes on the inside of the battery case, and on the outside of the battery case to capacitively couple high frequency, bidirectional, signals through the case that may be modulated by the data being sent. With the addition of a low-cost circuit, the datalink may use existing firmware in the BMS to communicate with a data terminal outside of the battery's case.

Additionally, the capacitively, coupled datalink may provide electrical isolation from the battery voltage. This may be required when batteries are connected in series and each battery added to the series connection has a common mode voltage equal to the sum of the battery voltages below it.

In situations such as when power consumption of circuitry needs to be minimized, and the transmitter and receiver should only be powered when the data terminal reader needs to communicate with the BMS, or other circuitry inside an enclosure, a sensor, such as a magnetic sensor, may be provided to detect the external data terminal reader.

These and other objectives and advantages may become apparent from the following description taken in conjunction with the accompanying drawings.

### DESCRIPTION OF THE FIGURES

FIG. 1 is a block diagram of a sealed battery having a BMS, in accordance with the present invention;

FIG. 2 is a block diagram of a sealed battery having a BMS and a capacitively coupled data link, in accordance with the present invention;

FIG. 3 is a block diagram of a transmitter in accordance with the present invention;

FIG. 4 is a block diagram of a receiver in accordance with the present invention;

FIG. 5 is an illustration of a transmitter and receiver mounted inside a battery case, in accordance with the present invention;

FIG. 6 is an illustration of a transmitter and receiver mounted in a plastic box, such as to mount on an external side of a battery case, in accordance with the present invention; and

FIG. 7 is a schematic drawing of a transmitter and a receiver in accordance with the present invention.

### DESCRIPTION OF THE PREFERRED EMBODIMENTS

While this invention is susceptible of embodiments in many different forms, there will be described herein in detail, a specific embodiment thereof with the understanding that the present disclosure is to be considered an exemplification of the principles of the invention and is not intended to limit the invention to the specific embodiment illustrated.

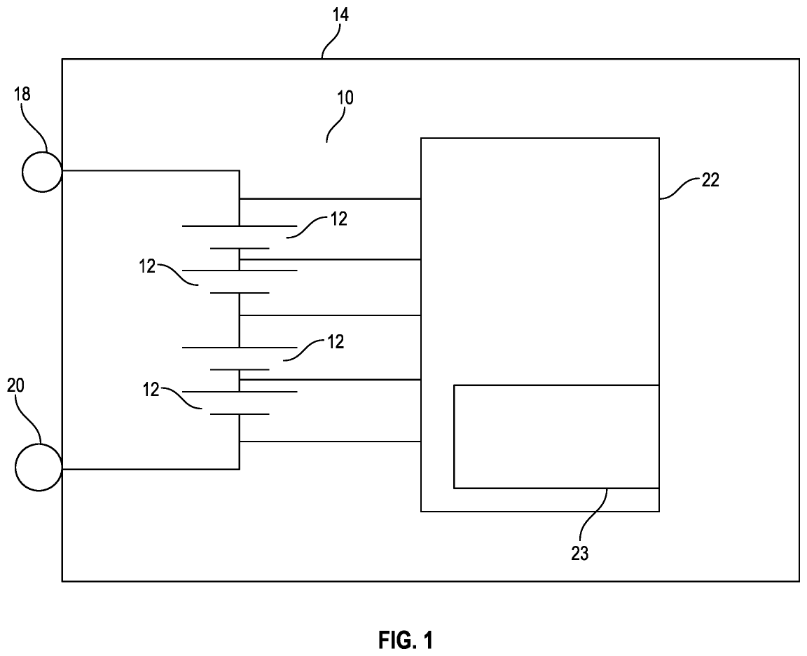

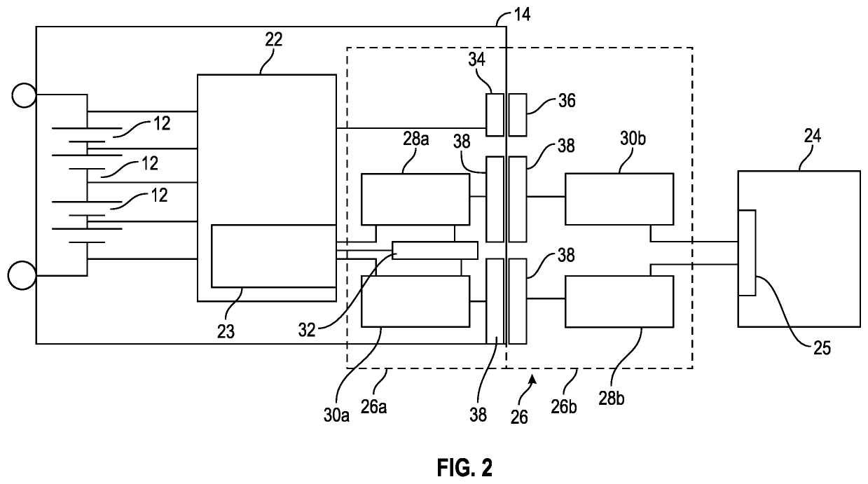

Referring to FIGS. 1 and 2, a battery, generally designated 1 may include one or more electrochemical cells 12, such as lithium ion cells, disposed within an interior of a battery case 14. The case 14 may be substantially sealed, such as to prevent, or otherwise minimize, entry of water, or other contaminants, into case 14. The cells 12 may be arranged in series between a positive battery terminal 18 and a negative battery terminal 20, as illustrated in FIGS. 1 and 2, although other arrangement of the cells 12 between the positive battery terminal 18 and the negative battery terminal 20 are contemplated, depending upon such factors as the desired power and voltage output of the battery 10.

The battery 10 may further include a conventional battery management system, or BMS, 22, which may include an interior date communications port 23, which may be a serial data communications port. In order to communicate with the INS 22 via the interior data communications port 23, a data terminal 24 (FIG. 2) disposed outside of the case 14 may be provided. The data terminal 24 may include an external data communications port 25. The external data communications port 25 may be a serial data communications port.

As noted above, in certain situations it may be desirable for the battery case 14 to be sealed. For example, the battery case of a marine battery may be sealed to prevent, or otherwise limit, water from entering the battery case 14 and damaging components therein. In accordance with the present invention, and as illustrated in FIG. 2, a capacitively coupled data link 26, which may be a serial data link, may enable communication between the BMS 22 disposed inside the sealed battery case 14 and the data terminal 24 outside of the sealed battery case 14, without a conventional connector, as such conventional connector may compromise the integrity of a sealed battery case 14 and may also be subject to breakage while the battery is being handled.

The capacitively coupled data link 26 may comprise an interior data link ion 26a, which may be physically disposed inside the battery case 14 and an exterior data link portion, 26b, which may be physically disposed outside the battery case 14.

The interior data link portion 26a may include an interior transceiver, which may comprise an interior receiver 28a and an interior transmitter 30a. As discussed below, the interior data link port on 26a may also include a power switch 32 and a sensor 34, such as a magnetic sensor. Similarly, the exterior data link portion 26b may include an exterior receiver 28b (associated with the interior transmitter 30a) and an exterior transmitter 30b (associated with the interior receiver 28a). As discussed below, the exterior data link portion 28b may also include a sensor actuator, such as a magnet 36.

Each of the interior and exterior receivers 28a, 28b, and the interior and exterior transmitters 30a, 30b, may include respective electrodes 38, which may be placed on, and engage, the respective inside surface and the outside surface of the battery case 14. Specifically, the electrode 38 of the interior receiver 28a is placed opposite the electrode 30 of the exterior transmitter 30b, and the electrode 38 exterior receiver 28b is placed opposite the electrode 38 of the interior transmitter 30a. The battery case 14 as a whole, or at least the portion of the battery case 14 between the opposing electrodes 38 may be made of plastic, or such other material to properly function as a dielectric, such that the respective opposing electrodes 38 cooperatively function as a capacitor.

The data communication between the data terminal 24 and the BMS 22 over the data link 26 may be used such as to read the battery's state of health, to recalibrate measurement functions such as cell voltages and current measurements, read battery events that may be recorded by the BMS, such as temperature extremes, short circuits, operating time, charging time, and the like. The data communication may also provide a method to update BMS firmware with new firmware revisions.

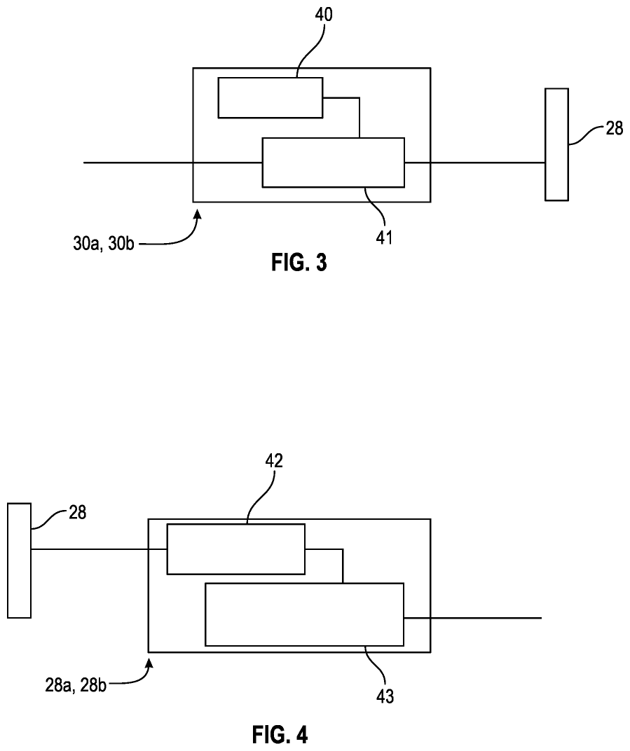

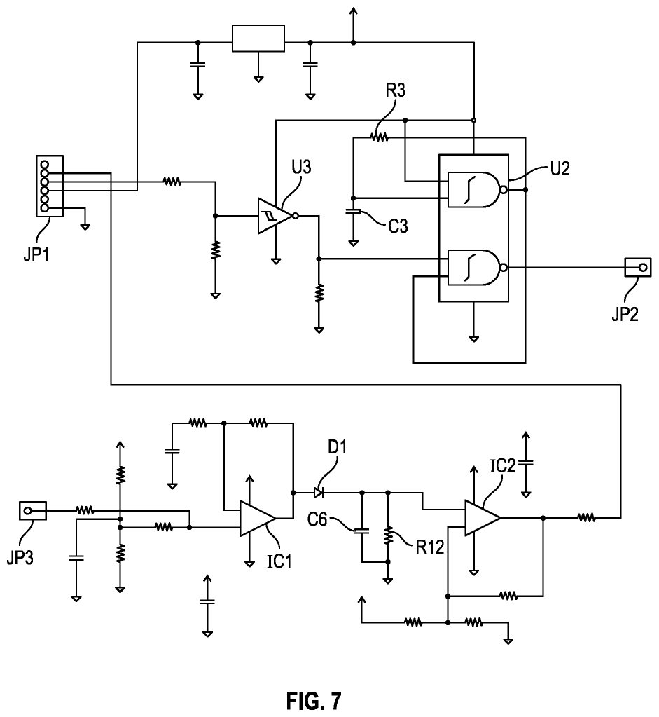

One embodiment of a transmitter, which may be utilized as either or both of the interior transmitter 30a or exterior transmitter 30b, is illustrated in block diagram in FIG. 3 and in schematic form in FIG. 7. The transmitters 30a, 30b, may include an oscillator 40 coupled to a modulator 41.

Referring to FIGS. 3 and 7, a carrier signal May be generated by the oscillator 40 in the transmitter circuit, which may be comprised of two integrated circuits (ICs), U2, U3 (FIG. 7), and associated resistors and capacitors. IC U2 may comprise a first NAND gate having input pins 1 and 2, and an output pin 7, and a second NAND gate having input pins 5 and 6, and an output pin 3. U2, pins 1, 2, and 7, along with resistor R3 and capacitor C3 create the relaxation oscillator 40. The oscillator frequency may be controlled by the values of resistor R3 and capacitor C3. Alternate implementations of the oscillator may also be used as a carrier signal generator. All that may, be required is a signal source with the desired frequency.

The transmitter may use a form of amplitude modulation known as ON-OFF keying (also known as OOK). The second gate of U2 may be used as a carrier signal gate. As illustrated in FIG. 7, the serial data to be transmitted may be connected to pin 4 of connector JP1. The serial data may be buffered by U3 and connected as an input to pin 5 of the second NAND gate. The output, pin 3 of the second NAND gate of U2, is the modulated carrier signal, whish may be connected to the transmitting plate of the respective coupling capacitor 28 through connector JP2.

One embodiment of a receiver, which may be utilized as either or both of the interior receiver 28a or exterior receiver 26b, is illustrated in FIGS. 4 and 7. The receivers 26a, 28b, may include an amplifier 42 coupled to a demodulator 43.

The electrode 28 of the receiving coupling capacitor may be connected to JP3 (FIG. 7). An amplifier, IC1, and associated resistors and capacitors may implement an amplifier with a signal gain of ten. The gain of this amplifier may be adjusted, increased or decreased, to meet the signal amplification requirements to reliably receive the signal from the associated transmitter.

The demodulator components diode D1, capacitor C6, and resistor R12 may implement an envelope detector.

A comparator, IC2, may implement a basic data slicer, which may convert the demodulated signal back into a digital compatible serial data stream. The serial output is output on pin 5 of JP1.

There may be situations in which power consumption of circuitry needs to be minimized, and the first and second transmitters 30a, 30b, and first and second receivers 28a, 28b should only be powered at certain times, such as when the data terminal 24 needs to communicate with the BMS, or other circuitry inside the battery case 14. This may be accomplished utilizing the magnetic sensor 34 and the magnet 36.

FIG. 2 illustrates use of the mantic sensor 34 disposed in the sealed case 14, and the activating magnet 36. When the magnet 36 is brought into the proximity of the case 14, the magnetic sensor 34, which will detect the magnetic field of the magnet 36, which is monitored by the BMS 22, which will provide a signal to the power switch 32. The BMS 22 will then provide power to the interior transmitter 30a and interior receiver 28a, through the power switch 32.

By using the magnet 36 and associated magnetic sensor 34, the interior transmitter 30a and interior receiver 28a, should only consume power when needed. In general, power consumption of the magnetic sensor 34 is very low compared to the power consumption of the interior transmitter 30a and interior receiver 28a.

The data link 10 lay provide electrical isolation from the battery voltage when the battery cells 12 are connected in series. With electrical isolation, a data terminal can safely communicate with each of the battery cells 12 in the series connection.

There may be assorted variations of the actual serial data communication, such as carrier frequency, data rate, data format, and the size of actual metal electrodes.

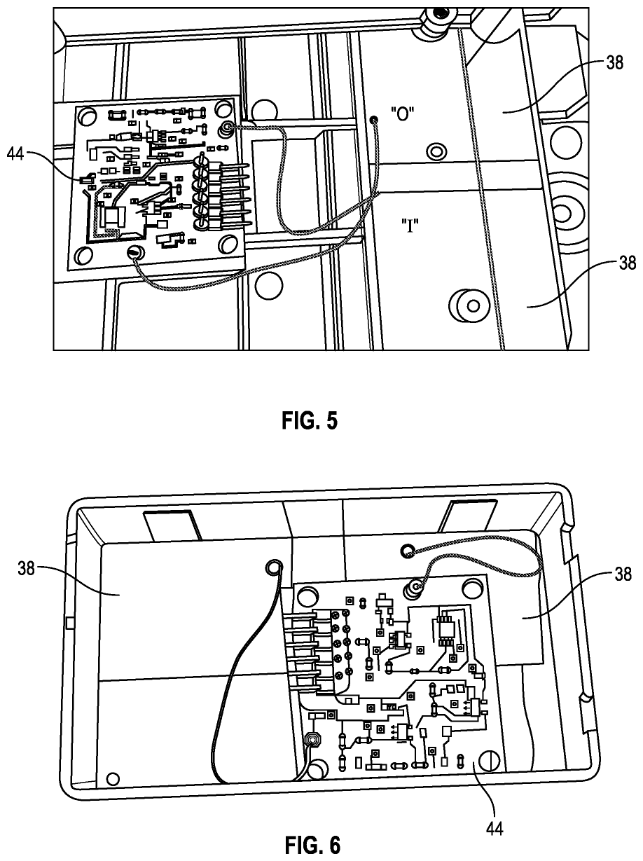

One particular embodiment is illustrated in FIGS. 5 and 6.

FIG. 5 shows a printed circuit board 44 with the transmitter and receiver circuitry mounted inside the battery case 14. The transmitters output is connected to the electrode labeled “O”. The receivers input is connected to the electrode labeled “I”. Several of the pins on the 6-pin connector may be used to connected to the serial data port on the HMS 22 in addition to power supply leads.

FIG. 6 illustrates the transmitter and receiver mounted in a plastic to use on the external side of the battery case 14. The 6-pin connector may be is used to connect the serial port on the data terminal end to provide power to the transmitter and receiver board.

In operation, the input electrode of the exterior receiver 28b may be aligned with output electrode 38 of the interior transmitter 30a inside of the battery case 14. Additionally, the output electrode 38 of the exterior transmitter 30b on the outside of the battery case 14 may be aligned with input electrode 38 of the interior receiver 28a on the inside of the battery case 14.

Utilizing a discrete electrode 38 for each of the transmitters 30a, 30b, and each of the receivers 28a, 28b, permits duplex data traffic. It is contemplated that one could use a single, shared interior electrode 38 for both the interior transmitter 30a and interior receiver 28a, and a single, shared exterior electrode 38 for both the exterior transmitter 30b and exterior receiver 28a, for half-duplex data traffic.

In the embodiment illustrated in FIGS. 5 and 6, serial data was exchanged between the data terminal located outside of the battery case and the BMS 22 located inside the battery case 14. A baud rate of 9600 baud was used in the demonstration. The modulated carrier signal was capacitively coupled, using copper foil electrodes, which were aligned as described above.

It is to be understood that this disclosure is not intended to limit the invention to any particular form described, but to the contrary, the invention is intended to include all modifications, alternatives and equivalents falling within the spirit and scope of the invention.

1. A capacitively coupled data link for a battery, the battery comprising a plurality of electrically interconnected battery cells and a battery management system adapted to monitor and/or control battery functions, wherein the battery is disposed in a sealed battery case, wherein the data link communicates data between the battery management system and a data terminal disposed outside of the battery case, the data link comprising:
an interior data link portion communicatively coupled to the battery management system, the interior data link portion comprising an interior electrode disposed on an inside surface of the battery case and an interior transceiver disposed inside of the battery case and coupled to the interior electrode; and
an exterior data link portion communicatively coupled to data terminal, the exterior data link portion comprising an exterior electrode disposed on an outside surface of the battery case opposite the interior electrode, and an exterior transceiver disposed outside of the battery case and coupled to the exterior electrode;
wherein the interior electrode, the exterior electrode and the battery case disposed therebetween form a capacitive communication link between the interior data link portion and the exterior data link portion.

2. The capacitively coupled data link of claim 1, wherein the interior data link portion includes a sensor for detecting a presence of a sensor actuator, the sensor actuator disposed outside of the battery case, and a switch operable in response to the detected presence of the sensor actuator for turning on the interior transceiver.

3. The capacitively coupled data link of claim 2, wherein the switch is operable under control of the battery management system.

4. The capacitively coupled data link of claim 3, wherein the sensor comprises a magnetic sensor and the sensor actuator comprises a magnet.

5. The capacitively coupled data link of claim 4, wherein the exterior transceiver is disposed in an exterior transceiver housing and the magnet is disposed within the exterior transceiver housing.

6. The capacitively coupled data link of claim 1, wherein the battery case is substantially sealed from entry of water.

7. The capacitively coupled data link of claim 1, wherein
the interior electrode comprises an interior transmitter electrode and an interior receiver electrode, and the interior transceiver comprises an interior transmitter coupled to the interior transmitter electrode and an interior receiver coupled to the interior receiver electrode;
the exterior electrode comprises an exterior transmitter electrode and an exterior receiver electrode, and the exterior transceiver comprises an exterior transmitter coupled to the exterior transmitter electrode and an exterior receiver coupled to the exterior receiver electrode; and
the interior transmitter electrode is disposed opposite the exterior receiver electrode and the exterior transmitter electrode is disposed opposite the interior receiver electrode.

8. The capacitively coupled data link of claim 1, wherein each of the interior and exterior transceivers transmit utilizing amplitude modulation.

9. The capacitively coupled data link of claim 8, wherein the amplitude modulation comprises ON-OFF keying.

10. The capacitively coupled data link of claim 1, wherein the interior and exterior transceivers comprise serial data transceivers.

11. The capacitively coupled data link of claim 1, wherein the interior and exterior electrodes are formed of copper foil.

12. A capacitively coupled serial data link for a battery, the battery comprising a plurality of electrically interconnected battery cells and a battery management system adapted to monitor and/or control battery functions, wherein the battery is disposed in a sealed battery case, wherein the serial data link communicates serial data between the battery management system and a data terminal disposed outside of the battery case, the serial data link comprising:
an interior data link portion communicatively coupled to the battery management system, the interior data link portion comprising an interior transmitter electrode and an interior receiver electrode, each of the interior transmitter electrode and the interior receiver electrode disposed on an inside surface of the battery case, and an interior transceiver comprising an interior transmitter and an interior receiver, disposed inside of the battery case and coupled to the interior electrodes; and
an exterior data link portion communicatively coupled to data terminal, the exterior data link portion comprising an exterior transmitter electrode and an exterior receiver electrode, each of the exterior transmitter electrode and exterior receiver electrode disposed on an outside surface of the battery case opposite the corresponding interior electrodes, and an exterior transceiver disposed outside of the battery case coupled to the exterior electrodes;
wherein the interior transmitter electrode and the interior receiver electrode, the corresponding exterior receiver electrode and transmitter electrode, and the battery case disposed therebetween form a duplex capacitive serial communication link for communicating data between the battery management system and the data terminal via the interior data link portion and the exterior data link portion.

13. The capacitively serial coupled data link of claim 12, wherein the interior data link portion includes:
a sensor for detecting a presence of a sensor actuator disposed outside of the battery case; and
a switch operable in response to the detected presence of the sensor actuator for turning on the interior transceiver.

14. The capacitively coupled serial data link of claim 13, wherein the switch is operable under control of the battery management system.

15. The capacitively coupled serial data link of claim 14, wherein the sensor comprises a magnetic sensor and the sensor actuator comprises a magnet.

16. The capacitively coupled serial data link of claim 15, wherein the exterior transceiver is disposed in an exterior transceiver housing and the magnet is disposed within the exterior transceiver housing. electrode.

17. The capacitively coupled data link of claim 12, wherein each of the interior and exterior transceivers transmit utilizing amplitude modulation.

18. The capacitively coupled data link of claim 17, wherein the amplitude modulation comprises ON-OFF keying.

19. A capacitively coupled serial data link for a battery, the battery comprising a plurality of interconnected battery cells and a battery management system adapted to monitor and/or control battery functions, wherein the battery is disposed in a sealed battery case, wherein the serial data link communicates serial data between the battery management system and a data terminal disposed outside of the battery case, the serial data link comprising:
an interior data link portion communicatively coupled to the battery management system, the interior data link portion comprising an interior transmitter electrode and an interior receiver electrode, each of the interior transmitter electrode and the interior receiver electrode disposed on an inside surface of the battery case, and an interior transceiver comprising an interior transmitter and an interior receiver, disposed inside of the battery case and coupled to the interior electrodes; and
an exterior data link portion communicatively coupled to data terminal, the exterior data link portion comprising an exterior transmitter electrode and an exterior receiver electrode, each of the exterior transmitter electrode and exterior receiver electrode disposed on an outside surface of the battery case opposite the corresponding interior electrodes, and an exterior transceiver disposed outside of the battery case coupled to the exterior electrodes;
wherein the interior transmitter electrode and the interior receiver electrode, the corresponding exterior receiver electrode and transmitter electrode, and the battery case disposed therebetween form a duplex capacitive serial communication link for communicating data between the battery management system and the data terminal via the interior data link portion and the exterior data link portion; and
wherein the interior data link portion includes a magnetic sensor for detecting a presence of a magnet proximally disposed outside of the battery case and a switch operable under control of the battery management system in response to the detected presence of the magnet for turning on the interior transceiver.

20. The capacitively coupled serial data link of claim 19, wherein the exterior transceiver is disposed in an exterior transceiver housing and the magnet is disposed within the exterior transceiver housing.

21. (canceled)
